(19) United States
(12) Patent Application Publication
(10) Pub. No.: US 2011/0168253 A1
(43) Pub. Date: Jul. 14, 2011

(54) ELECTRODE SUBSTRATE AND PHOTOELECTRIC TRANSFORMATION DEVICE

(75) Inventors: Yukika YAMADA, Yokohama (JP); Tadao YAGI, Yokohama (JP); Yoshitaka TERAO, Yokohama (JP)

(73) Assignee: Samsung SDI Co., Ltd., Yongin-si (KR)

(21) Appl. No.: 12/978,247

(22) Filed: Dec. 23, 2010

(30) Foreign Application Priority Data
Dec. 25, 2009 (JP) 2009-295943
Nov. 11, 2010 (KR) 2010-0112203

(51) Int. Cl. H01L 31/0224; H01L 51/44

(52) U.S. Cl. 136/256

(57) ABSTRACT

An electrode substrate of a photoelectric transformation device includes a transparent conductive substrate, a current-collecting electrode disposed on the transparent conductive substrate, and a coating film coating the surface of the current-collecting electrode. The coating film includes a combustion product of a glass paste composition applied on the current-collecting electrode. The glass paste composition includes a filler made of a material that does not melt at a temperature which is not higher than a glass transition temperature or a phase transition temperature of the transparent conductive substrate.

### CLAIM OF PRIORITY

This application makes reference to, incorporates into this specification the entire contents of, and claims all benefits accruing under 35 U.S.C. §119 from an application earlier filed in the Japanese Patent Office filed on Dec. 25, 2009 and there duly assigned Japanese Patent Application No. 2009-295943, and an application earlier filed in the Korean Intellectual Property Office filed on Nov. 11, 2010 and there duly assigned Korean Patent Application No. 10-2010-0112203.

### BACKGROUND OF THE INVENTION

1. Field of the Invention

This disclosure relates to an electrode substrate for a photoelectric transformation device and a photoelectric transformation device including the electrode substrate.

2. Description of the Related Art

Studies on a photoelectric transformation device such as a solar cell and the like transforming photoenergy into electrical energy have been actively performed to provide clean energy having little environmental impact.

### SUMMARY OF THE INVENTION

One aspect of the present invention provides an improved electrode substrate and an improved photoelectric transformation device including the electrode substrate.

Another aspect of the present invention provides an electrode substrate that may prevent a coating film coating a current-collecting electrode from generating cracks while providing sufficient electrolyte resistance.

A further aspect of the present invention provides a photoelectric transformation device including the electrode substrate.

According to one aspect of the present invention, an electrode substrate is provided which includes a transparent conductive substrate, a current-collecting electrode disposed on the transparent conductive substrate, and a coating film coating the surface of the current-collecting electrode. The coating film includes a combustion product of a glass paste composition applied on the surface of the current-collecting electrode. The glass paste composition includes a filler including a material that does not melt at a temperature which is not higher than a glass transition temperature or a phase transition temperature of the transparent conductive substrate.

The filler may be included in an amount of about 0.1 wt % to about 50 wt % based on the total weight of the glass paste composition.

The filler may include at least one of Al₂O₃, SiO₂, TiO₂, ZnO₂, SnO₂, MgO, and CaO.

The filler may have a particle diameter ranging from about 0.1 μm to about 10 μm.

According to another aspect of the present invention, provided is a photoelectric transformation device including the electrode substrate.

The photoelectric transformation device may be a dye-sensitized solar cell.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view showing a photoelectric transformation device constructed as one embodiment according to the principles of the present invention;

FIG. 2 is a schematic view showing the operation mechanism of the photoelectric transformation device in FIG. 1;

FIGS. 3A and 3B are schematic views showing coating films disposed on an electrode substrate of a photoelectric transformation device in FIG. 1;

FIG. 4A explains a hole generation situation when dirt is included in a glass paste composition;

FIG. 4B explains a hole generation situation when a glass paste composition is over-sintered;

FIGS. 5A to 5D are photographs of the surface of a coating film examined taken with a metal microscope;

FIGS. 6A to 6C are photographs of the surface of a coating film examined taken with a laser microscope;

FIGS. 7A and 7B are photographs of the surface of a filler itself examined with an electron microscope;

FIG. 8A is a synopsis showing a testing method using a strength tester;

FIG. 8B shows a view enlarging a region A surrounded with a dotted line in FIG. 8A;

FIG. 9 is a graph showing strength test results; and

FIG. 10 is a graph showing a relationship between transformation efficiency η and time of photoelectric transformation cells according to Examples 3 and 8 and Comparative Example 1.

### DETAILED DESCRIPTION OF THE INVENTION

As example of a solar cell, a silicon-based solar cell such as a monocrystalline silicon solar cell, a polysilicon solar cell, an amorphous silicon solar cell, and the like; and a compound semiconductor solar cell using a compound semiconductor such as cadmium telluride, copper indium selenide, and the like instead of silicon, have been commercialized or researched.

The solar cells, however, may have a high manufacturing cost. It is difficult to obtain a source material and takes long time to get energy payback.

Although many solar cells using an organic material aiming for a device with a large area and a low cost have been also suggested, the device still has insufficient transformation efficiency or low durability.

On the other hand, research has been made on a dye sensitized solar cell using a semiconductor porous body sensitized by a dye. As a dye sensitized solar cell, a Gratzel cell, in which a dye is fixed on the surface of a porous titanium oxide thin film, has been recently developed and researched.

A Gratzel cell is a dye-sensitized photoelectric transformation cell including a titanium oxide porous thin film layer spectral-sensitized by a ruthenium complex dye as a working electrode, an electrolyte layer including urea as a main component, and a counter electrode.

The Gratzel cell is advantageous because the Gratzel cell may provide an inexpensive photoelectric transformation device, since the Gratzel cell includes an inexpensive oxide semiconductor such as titanium oxide. The Gratzel cell may accomplish relatively high transformation efficiency, since a ruthenium complex dye used therein is widely adsorbed in a visible ray region. The dye sensitized solar cell is reported to have a transformation efficiency of over 12% and thus, to ensure sufficient practicality compared to a silicon-based solar cell.

When a photoelectric transformation device such as a solar cell is fabricated to have a large area, however, the photoelectric transformation device may generally have deteriorated photoelectric transformation efficiency, since the generated current is transformed into Joule heat in a low-conductive substrate such as a transparent electrode. In order to overcome the problem, an attempt to decrease electrical energy loss in a solar cell has been made by forming a highly conductive metal line such as silver and copper in a grid to provide a current-collecting electrode (hereinafter, referred to as a grid electrode). When the current-collecting electrode is applied to a dye sensitized solar cell, the current-collecting electrode needs to be prevented from corrosion by an electrolyte including an iodine element, that is to say, to secure electrolyte resistance.

A technology also has been suggested that a current-collecting electrode may be coated or protected with a glass material having a low melting point, after forming the current-collecting electrode. In addition, a plural of coating films may be disposed on a current-collecting electrode, or a current-collecting electrode itself may be made of a material having excellent electrolyte-resistance without a coating film. Furthermore, it has been suggested that a current-collecting electrode is made of a material having a small linear expansion coefficient difference with a glass material for a coating film to prevent a cracking on the coating film.

But, the above technologies cannot secure sufficient electrolyte resistance and may undesirably renders complicate cell structures. In addition, a material with excellent electrolyte-resistance may reduce performance of a solar cell. When a glass material for forming a coating film is sintered, the glass material may cause a stress on the coating film and a crack thereon.

Exemplary embodiments of the present invention will hereinafter be described in detail. However, these embodiments are only exemplary, and the present invention is not limited thereto.

In the drawings, the thickness of layers, films, panels, regions, etc., are exaggerated for clarity. Like reference numerals designate like elements throughout the specification. It will be understood that when an element such as a layer, a film, a region, or a substrate is referred to as being “on” another element, it may be directly on the other element, or intervening elements may also be present. In contrast, when an element is referred to as being “directly on” another element, there are no intervening elements present.

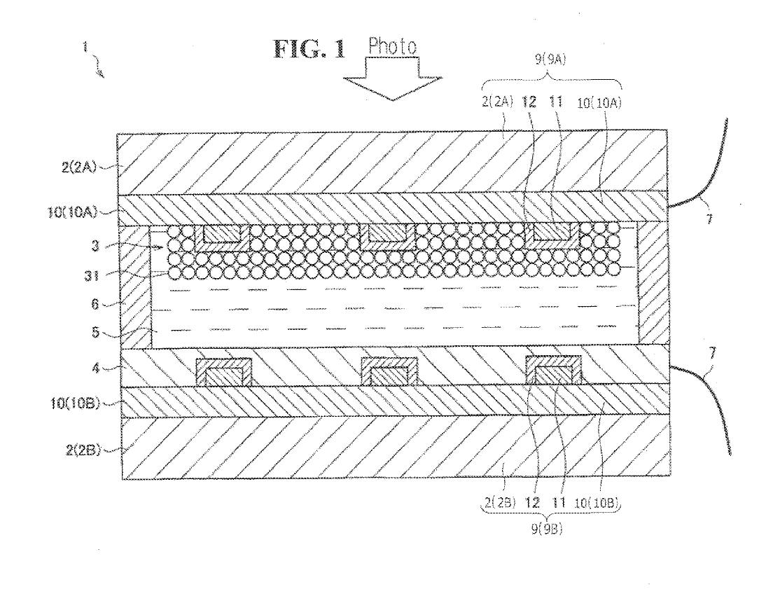

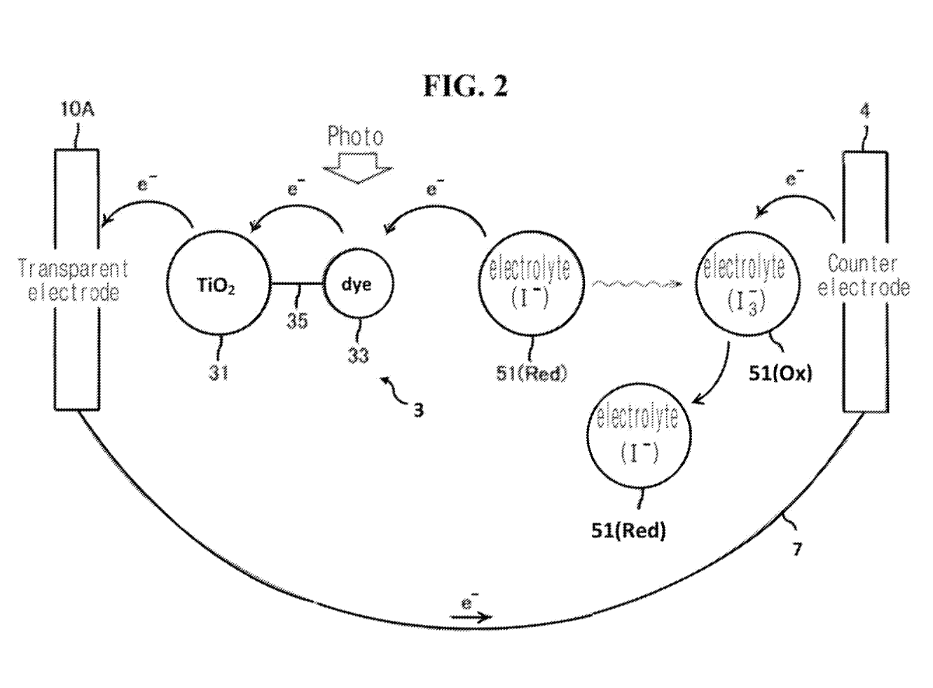

Referring to FIGS. 1 and 2, illustrated is a photoelectric transformation device constructed as one embodiment according to the principles of the present invention.

FIG. 1 is a cross-sectional view of the photoelectric transformation device constructed as the embodiment according to the principles of the present invention, and FIG. 2 is a schematic view showing mechanism of the photoelectric transformation device shown in FIG. 1.

FIG. 1 shows a dye sensitized solar cell 1 including a Gratzel cell as an example of the photoelectric transformation device.

Referring to FIG. 1, dye sensitized solar cell 1 constructed as the embodiment according to the principles of the present invention includes two electrodes 9A and 9B including two substrates 2A and 2B, a photoelectrode 3, a counter electrode 4, an electrolyte 5, a spacer 6, and a lead wire 7.

Two substrates 2A and 2B are disposed to face each other with a predetermined gap therebetween. Substrates 2A and 2B have no specific limit in a material, as long as the material for forming substrates 2A and 2B is a transparent material having a little light adsorption from the visible ray region to the near infrared ray region of extraneous light (solar light etc.).

Each one of substrates 2A and 2B may be formed as, for example, a glass substrate such as quartz, common glass, the borosilicate glass Schott BK7, lead glass, or the like, or a resin substrate such as polyethylene terephthalate, polyethylene naphthalate, polyimide, polyester, polyethylene, polycarbonate, polyvinylbutyrate, polypropylene, tetraacetyl cellulose, syndiotactic polystyrene, polyphenylene sulfide, polyarylate, polysulfone, polyester sulfone, polyetherimide, cyclic polyolefin, phenoxy bromide, vinyl chloride, or the like.

Each one of electrode substrates 9A and 9B being one example of the transparent conductive substrate includes a transparent electrode 10, a current-collecting electrode 11, and a coating film 12, are respectively formed on a surface of the two substrates 2A and 2B in at least a light incident side from the outside. In order to improve photoelectric transformation efficiency, electrode substrates 9A and 9B may have as much decreased sheet resistance (surface resistance) as possible, for example, up to 20 Ω/cm²(Ω/sq) or less.

It is not necessary, however, to form the transparent electrode 10B, the current-collecting electrode 11 and the coating film 12, on the surface of substrate 2B facing substrate 2A. Even if the transparent electrode 10B, the current-collecting electrode 11 and the coating film are formed on the surface of substrate 2B, they does not need to be transparent, i.e., adsorb less extraneous light in a region from the visible ray to the near infrared ray coming out of dye sensitized solar cell 1.

Transparent electrodes 10A and 10B are respectively stacked on one side of two substrates 2A and 2B to face each other and are formed of, for example, a transparent conductive oxide (TCO). The transparent conductive oxide has no specific limit, as long as it is an electrically conductive material adsorbing less light in the region from the visible ray to the infrared ray of the extraneous light coming out of the photoelectric transformation device 1. But, the transparent conductive oxide may include a metal oxide having good electrical conductivity such as indium tin oxide (ITO), tin oxide (SnO₂), fluorine-doped tin oxide (FTO), antimony-included tin oxide (ITO/ATO), zinc oxide (ZnO₂), and the like.

Current-collecting electrode 11 is a metal line formed on a surface of each one of transparent electrodes 10A and 10B, and plays a role of transmitting excited electrons reached at electrode substrate 9 to lead wire 7 through a metal oxide particulate (i.e., inorganic metal oxide semiconductor particulates) 31. Referring to FIG. 2, photoelectrode 3 has a structure that a large amount of sensitizing dye units 33 are continuously formed on the surface of inorganic metal oxide semiconductor particulates 31, which will be described later.

Current-collecting electrode 11 may prevent the deterioration of the photoelectric conversion efficiency by converting the generated current into joule heat in a substrate having relatively low conductivity such as transparent conductive oxides, due to the high sheet resistance, which is about 10 Ω/sq or less, of the transparent electrode 10.

In this regard, current-collecting electrode 11 is electrically connected to transparent electrode 10A or 10B and may include a highly conductive metal such as Ag, Ag/Pd alloy, Cu, Au, Ni, Ti, Co, Cr, Al, and the like or its alloy. Current-collecting electrode 11 may have no specific limit in the wire pattern, as long as the pattern shape decreases the electrical energy loss but may have a predetermined shape such as a lattice, stripe, rectangular shape, comb tooth shape, and the like.

Since current-collecting electrode 11 is formed of a metal such as gold, silver, copper, platinum, aluminum, nickel, titanium, solder, or the like, current-collecting electrode 11 may be corroded by an electrolyte 5 including iodine ions (I⁻/I₃⁻ or the like).

According to one embodiment of the present invention, a photoelectric transformation device 1 includes coating film 12.

As described above, coating film 12 coats current-collecting electrode 11 to prevent the corrosion of current-collecting electrode 11 by electrolyte solution 5. Coating film 12 is disposed by coating a glass paste composition having a low melting point on the surface of current-collecting electrode 11 and sintering the glass paste composition. Accordingly, coating film 12 includes a combustion product, that is, the remaining part of the glass paste composition after the glass paste composition is sintered or burned-out (combusted).

The glass paste composition for forming coating film 12 is a paste composition including a glass frit, an organic binder, an organic solvent, an additive, and the like.

Coating film 12 will be described later.

In photoelectric transformation device 1, photoelectrode 3 may be formed as an inorganic metal oxide semiconductor layer having a photoelectric transformation function and formed as a porous layer

For example, as shown in FIG. 1, photoelectrode 3 is formed by laminating inorganic metal oxide semiconductor particulates 31 (hereinafter, referred to a “metal oxide particulate 31”) such as TiO₂ or the like on the surface of electrode substrate 9A. Photoelectrode 3 a porous body (nanoporous layer) including fine pores among the laminated metal oxide particulates 31. Photoelectrode 3 is formed as a porous body including a plurality of small pores and thus, may have an increased surface area. Accordingly, in photoelectrode 3, a large amount of sensitizing dye units 33 may be connected to the surface of metal oxide particulates 31 and thus the photoelectric transformation efficiency of dye sensitized solar cell 1 may be improved.

As shown in FIG. 2, sensitizing dye unit 33 is connected to the surface of metal oxide particulates 31 through a connecting group 35, providing a photoelectrode 3 in which an inorganic metal oxide semiconductor is sensitized. The term “connection” in this specification and in the claims indicates that an inorganic metal oxide semiconductor is chemically and physically bound with a sensitizing dye (for example, bound by adsorption or the like). Accordingly, the term “a connecting group” includes an anchor group or an adsorbing group as well as a chemical functional group.

FIG. 2 only schematically shows that one sensitizing dye unit 33 is connected to the surface of metal oxide particulate 31. In order to improve the electrical output of dye sensitized solar cell 1, it is preferable to connect the number of sensitizing dye units 33 to the surface of metal oxide particulates 31 as many as possible and to coat a plurality of sensitizing dye units 33 on the surface of metal oxide particulate 31 as wide as possible. When the number of sensitizing dye units 33 is excessively increased, an excited electron may be lost due to interaction among adjacent sensitizing dye units, 33, losing electrical energy. Thus, a co-adsorption material such as deoxycholic acid and the like may be used to coat the sensitizing dye units 33 with an appropriate distance from one another.

Photoelectrode 3 may be formed by laminating metal oxide particulates 31 having a primary particle with a number average particle diameter ranging from about 20 nm to about 100 nm in more than one layer. Photoelectrode 3 has a layer thickness of several micrometers (e.g., 10 urn or less). When photoelectrode 3 has a layer thickness of less than several micrometers, photoelectrode 3 may transmit more light and thus, may cause sensitizing dye unit 33 insufficiently excited, failing in securing efficient photoelectric transformation efficiency. On the other hand, when photoelectrode 3 has a layer thickness of more than several micrometers, a surface of photoelectrode 3 contacting electrolyte 5 is farther from an interface between the photoelectrode 3 and electrode substrate 9A. Thus, excited electrons may not be effectively transmitted to the surface of an electrode, failing in securing good transformation efficiency.

Hereinafter, metal oxide particulate 31 and sensitizing dye unit 33 for photoelectrode 3 constructed as one embodiment according to the principles of the present invention will be described in detail.

In general, an inorganic metal oxide semiconductor photoelectrically transforms light in a predetermined wavelength region but also, photoelectrically transforms light in the region from visible ray to near infrared ray when sensitizing dye unit 33 is connected to the surface of metal oxide particulate 31. A compound used for metal oxide particulate 31 has no specific limit as long as the compound enhances a photoelectric transformation function by being connected to a sensitizing dye unit 33. But, the compound used for metal oxide particulate 31 may be formed of, for example, titanium oxide, tin oxide, tungsten oxide, zinc oxide, indium oxide, niobium oxide, iron oxide, nickel oxide, cobalt oxide, strontium oxide, tantalum oxide, antimony oxide, oxides of lanthanide elements, yttrium oxide, vanadium oxide, and the like.

As the surface of metal oxide particulate 31 is sensitized by sensitizing dye unit 33, the conduction band of the inorganic metal oxide may be disposed where the inorganic metal oxide can easily receive electrons from a photoexcitation trap of sensitizing dye unit 33. In this regard, the compound for a metal oxide particulate 31 may be formed of, for example, titanium oxide, tin oxide, zinc oxide, niobium oxide, and the like. In addition, the compound for metal oxide particulate 31 may preferably include titanium oxide in terms of cost and environmental sanitation.

Metal oxide particulate 31 may be formed by a single kind of an inorganic metal oxide or by a combination of multiple kinds thereof.

Sensitizing dye unit 33 is not specifically limited as long as the metal oxide particulate 31 photoelectrically transforms a light in the region having no photoelectric transformation function (for example, in the region from visible ray to near infrared ray).

Sensitizing dye unit 33 may be formed of, for example, an azo-based dye, a quinacridone-based dye, a diketopyrrolopyrrole-based dye, a squarylium-based dye, a cyanine-based dye, a merocyanine-based dye, a triphenylmethane-based dye, a xanthene-based dye, a porphyrin-based dye, a chlorophyll-based dye, a ruthenium complex-based dye, an indigo-based dye, a perylene-based dye, a dioxadine-based dye, an anthraquinone-based dye, a phthalocyanine-based dye, a naphthalocyanine-based dye, and derivatives thereof or the like.

Sensitizing dye unit 33 may include a functional group of a connecting group 35 that is capable of connecting a dye to the surface of metal oxide particulate 31 in order to promptly transmit the excited electrons of the photo-excited dye into the conductive band of the inorganic metal oxide. The functional group is not specifically limited, as long as the functional group is a substituent connecting sensitizing dye unit 33 to the surface of metal oxide particulate 31 and promptly transmitting the excited electrons of the dye to the conductive band of the inorganic metal oxide. But, the functional group may be, for example, a carboxyl group, a hydroxyl group, a hydroxamic acid group, a sulfonic acid group, a phosphonic acid group, a phosphinic acid group or the like.

Counter electrode 4 may be a positive electrode in photoelectric transformation device 1 and disposed on the surface of transparent electrode 10B facing transparent electrode 10A on which photoelectrode 3 is formed. In other words, counter electrode 4 is disposed to face photoelectrode 3 on the surface of electrode substrate 9B in a region surrounded by two electrode substrates 9 and spacer 6.

A metal catalyst layer having electrical conductivity is disposed on a surface of counter electrode 4 facing photoelectrode 3.

The metal catalyst layer on counter electrode 4 may be formed of a conductive material, for example, a metal such as platinum, gold, silver, copper, aluminum, rhodium, indium, and the like, metal oxide such as indium tin oxide, tin oxide, fluorine doped tin oxide, or the like, zinc oxide, and the like, a conductive carbon material; or a conductive organic material, or a combination thereof.

Counter electrode 4 may have no specific limit in a layer thickness. The layer thickness of counter electrode 4, however, may range, for example, from about 5 nm to about 10 μm.

On the other hand, lead wires 7 are respectively connected to transparent electrode 10A on a side disposed with the photoelectrode 3 and counter electrode 4. Lead wire 7 from transparent electrode 10A is electrically connected with lead wire 7 from counter electrode 4 outside of dye sensitized solar cell 1 and forms a current circuit.

In addition, transparent electrode 10A and counter electrode 4 are partitioned by spacer 6 leaving a predetermined gap therebetween. Spacer 6 is formed along the circumference of transparent electrode 10A and counter electrode 4 and seals the space between transparent electrode 10A and counter electrode 4.

Spacer 6 may be a resin having a high sealing property and high corrosion resistance. For example, spacer 6 may be formed of a film thermoplastic resin, a photo-curable resin, an ionomer resin, a glass frit, and the like. The ionomer resin may be, for example, Himilan (trade name) manufactured by Mitsui DuPont Polychemical, or the like.

An electrolyte solution 5 is injected into the space between transparent electrode 10A and counter electrode 4 and is sealed therein by spacer 6.

Electrolyte solution 5 may include, for example, an electrolyte, a solvent, and various additives.

The electrolyte may include a redox electrolyte such as an I₃⁻/I⁻-based or Br₃⁻/Br⁻-based electrolyte. For example, the electrolyte may be formed of a mixture of I₂ and iodide (LiI, NaI, KI, CsI, MgI₂, CaI₂, CuI, tetraalkyl ammonium iodide, pyridinium iodide, imidazolium iodide, and the like), a mixture of Br₂ and bromide (LiBr etc.), an organic molten salt compound, and the like but is not limited thereto.

The organic molten salt compound may include a compound consisting of an organic cation and an inorganic or organic anion and has a melting point of a room temperature or less.

The organic cation included in the organic molten salt compound may include an aromatic cation and/or an aliphatic cation. The aromatic cation may be, for example, N-alkyl-N′-alkylimidazolium cations such as an N-methyl-N′-ethylimidazolium cation, an N-methyl-N′-n-propylimidazolium cation, an N-methyl-N′-n-hexylimidazolium cation, and the like or N-alkylpyridinium cations such as an N-hexylpyridinium cation, an N-butylpyridinium cation, and the like. The aliphatic cation may be, for example an N,N,N-trimethyl-N-propylammonium cation, N,N-methyl pyrrolidinium, and the like.

The inorganic or organic anion included in the organic molten salt compound may be, for example, halide ions such as chloride ions, bromide ions, iodide ions, or the like; inorganic anions such as phosphorus hexafluoride ions, boron tetrafluoride ions, methane sulphonic trifluoride ions, perchloric acid ions, hypochloric acid ions, chloric acid ions, sulfonic acid ions, phosphoric acid ions, or the like; or amide anions or imide anions such as bis(trifluoromethylsulfonyl)imide ions or the like.

The organic molten salt compound may be a compound disclosed in Inorganic Chemistry, vol. 35 (1996); p. 1168 to p. 1178.

The mentioned iodide, bromide, or the like may be used as a single or a mixture thereof.

A mixture of I₂ and iodide (LiI, NaI, KI, CsI, MgI₂, CaI₂, CuI, tetraalkylammonium iodide, pyridinium iodide, imidazolium iodide, and the like), may be used. Particularly, a combination of I₂ and iodide (e.g., I₂ and LiI), pyridinium iodide or imidazolium iodide, or the like are mixed to provide an electrolyte.

Electrolyte solution 5 may have an I₂ concentration ranging from about 0.01 M to about 0.5 M in a solvent. Either of iodide and bromide (a mixture thereof when used together) has a concentration ranging from about 0.1 M to about 15 M.

A solvent for electrolyte solution 5 may be a compound providing excellent ion conductivity. The solvent may be formed of, for example, ether compounds such as dioxane, diethylether, or the like; linear ethers such as ethylene glycol dialkylether, propylene glycol dialkylether, polyethylene glycol dialkylether, polypropylene glycol dialkylether, or the like; alcohols such as methanol, ethanol, ethylene glycol monoalkylether, propylene glycol monoalkylether, polyethylene glycol monoalkylether, polypropylene glycol monoalkylether, or the like; polyhydric alcohols such as ethylene glycol, propylene glycol, polyethylene glycol, polypropylene glycol, glycerine, or the like; nitrile compounds such as acetonitrile, glutarodinitrile; methoxy acetonitrile, propionitrile, benzonitrile, or the like; carbonate compounds such as ethylene carbonate, propylene carbonate, or the like; heterocyclic ring compounds such as 3-methyl-2-oxazolidinone or the like; aprotic polar materials such as dimethyl sulfoxide, sulfolane, or the like; or water and the like.

These solvents may be used singularly or as a mixture thereof.

A solid (including a gel) solvent may be prepared by adding a polymer to a liquid solvent. In this case, the solid solvent may be prepared by adding a polymer such as polyacrylonitrile, poly vinylidene fluoride, or the like to the liquid solvent. Alternatively, the solid solvent may be prepared by polymerizing a multi-functional monomer including an ethylenic unsaturated group in the liquid solvent.

The solvent for electrolyte solution 5 may include an ionic liquid that exists as a liquid at a room temperature. The ionic liquid may suppress evaporation of electrolyte solution 5, resulting in improvement of durability of a photoelectric transformation device 1.

Electrolyte solution 5 may also include a hole transport material such as CuI, CuSCN (these compounds are a p-type semiconductor requiring no liquid medium and act as an electrolyte), or 2,2′,7,7′-tetrakis(N,N-di-p-methoxyphenylamine)-9,9′-spirobifluorene disclosed in Nature, vol. 395 (Oct. 8, 1998), p583 to p585, or the like.

Other additives may be further added to electrolyte solution 5 in order to improve durability or the electrical output of dye sensitized solar cell 1.

For example, inorganic salts such as magnesium iodide or the like may be added in order to improve durability of dye sensitized solar cell 1. Amines such as t-butyl pyridine, 2-picoline, 2,6-lutidine, or the like; steroids such as deoxy cholic acid or the like; monosaccharides or sugar alcohols such as glucose; glucosamine, glucuronic acid, or the like; disaccharides such as maltose or the like; linear oligosaccharides such as raffinose or the like; cyclic oligosaccharides such as cyclodextrin or the like; or hydrolysis oligosaccharides such as lacto oligosaccharide or the like may be added in order to improve electrical output of the dye sensitized solar cell 1.

Electrolyte solution 5 has no specific limit in the thickness but may be thin enough to prevent direct contact between counter electrode 4 and photoelectrode 3 adsorbing the dye. For example, electrolyte solution 5 may have a thickness ranging from about 0.1 μm to about 100 μm.

Hereinafter, referring to FIGS. 1 and 2, described is the working mechanism of a photoelectric transformation device constructed as an embodiment according to the principles of the present invention.

In a photoelectrode 3 including metal oxide particulates 31 and a sensitizing dye unit 33 connected to the surface of metal oxide particulates 31 through a connecting group 35, as shown in FIGS. 1 and 2, light (solar light) entering a cell through a substrate 2A is absorbed in sensitizing dye unit 33 connected to the surface of metal oxide particulates 31.

Sensitizing dye unit 33 absorbing light is excited from an electronic ground state by metal to ligand charge transfer (MLCT) and emits excited electrons. The excited electrons are injected into the conduction band of a metal oxide (e.g., TiO₂) metal oxide particulate 31 through connecting group 35. As a result, sensitizing dye unit 33 is oxidized.

Herein, sensitizing dye unit 33 may have a lower energy trap than the one of a metal oxide (semiconductor), so that the excited electrons may be efficiently injected into the metal oxide.

The excited electrons injected from the conduction band of a metal oxide reach an electrode substrate (a transparent electrode 10A) through other metal oxide particulates 31 and are lead to a counter electrode 4 through a lead wire 7.

On the other hand, sensitizing dye unit 33 lacking of electrons at an oxidation state due to the emission of the excited electrons receives electrons from an electrolyte 51 (Red) of a redox reducing body (for example, I⁻) and comes back to the ground state.

The electrolyte 51 (Ox) becoming oxidizing body (for example, I₃⁻) after supplying sensitizing dye unit 33 with electrons is diffused into counter electrode 4 and then, receives electrons from counter electrode 4 and goes back to the electrolyte 51 (Red) of a redox reducing body.

On the other hand, electrolyte 51 (Ox) may receive electrons, for example, from other electrolyte 51 (Red) through hopping conduction and the like as well as from counter electrode 4.

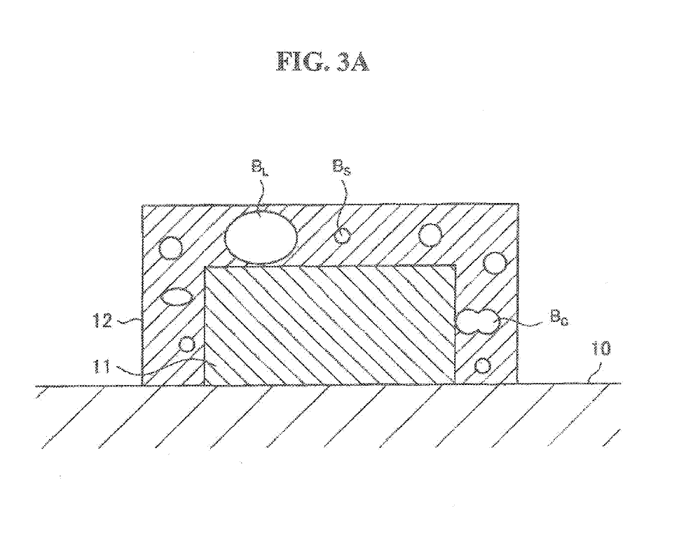

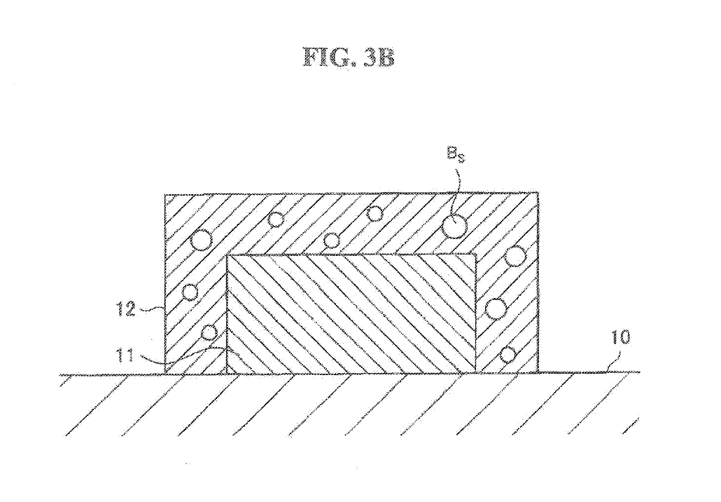

Hereinafter, illustrated is a coating film 12 in more detail referring to FIGS. 3A and 3B.

FIG. 3A is a schematic diagram showing a coating film disposed on an electrode substrate included in the photoelectric transformation device of FIG. 1.

Referring to FIG. 3A, an electrode substrate of one embodiment according to the principles of the present invention includes a transparent electrode 10, a current-collecting electrode 11, and a coating film 12.

As described above, a glass paste composition for forming coating film 12 may be a paste type including a glass frit, a binder resin, a solvent, an additive, and the like.

Hereinafter, illustrated is each component included in glass paste composition.

The glass frit may include other metal oxides, for example, SiO₂, B₂O₃, and P₂O₅ backbones to control a melting point and to secure chemical stability. For example, one glass or a mixture of more than two glasses with a low melting point such as SiO₂—Bi₂O₃-MOₓ-based, B₂O₃—Bi₂O₃-MOₓ-based, SiO₂—CaO—Na (K)₂O-MO-based, P₂O₅—MgO-MOₓ-based (M is more than one metal element), and the like may be used.

The binder resin may be completely combusted and thus, have no residue at a temperature where a substrate 2 is melted, that is to say, maintains no physical and chemical shape. Herein, the temperature where a substrate 2 maintains no physical and chemical shape indicates, in particular, the glass transition temperature or the phase transition temperature of substrate 2. For example, when a substrate 2 is formed of a transparent conductive oxide (TCO), the glass transition temperature of substrate 2 is about 600° C. and the like. The glass transition temperature of a non-crystalline material is the critical temperature at which the material changes its behavior from being ‘glassy’ to being ‘rubbery’. ‘Glassy’ in this context means hard and brittle (and therefore relatively easy to break), while ‘rubbery’ means elastic and flexible. The phase transition temperature of a material is the temperature at which the material changes from one phase to another phase.

Examples of the binder resin may include a ethylcellulose (EC) resin and also, polyvinylalcohol, polyethyleneglycol, (meth)acryl resin, and the like other than that.

The solvent for the glass paste composition has no particular limit. However, when a glass paste composition is dried too fast, the glass paste composition may be extracted as a solid during the manufacturing process of a photoelectric transformation device 1.

Accordingly, the solvent for the glass paste composition may have a boiling point of about 150° C. or higher and preferably, about 180° C. or higher. The solvent for the glass paste composition may include, for example, a terpene-based solvent (terpineol and the like) or a carbitol-based solvent (butylcarbitol, butylcarbitol acetate).

The glass paste composition may further include an additive to improve dispersion of glass frit or a resin if necessary.

This additive may include a polymer for controlling viscosity during the screen-printing and the like for improving dispersion of glass frit, a thickener for adjusting fluidity, a dispersing agent for improving dispersion, and the like.

The polymer may be, for example, polyvinylalcohol, polyethyleneglycol, ethylcellulose (EC), (meth)acrylic resin, and the like.

Examples of the thickener may include a cellulose-based resin such as ethylcellulose and the like or a polyoxyalkylene resin such as polyethyleneglycol and the like.

The dispersing agent may be, for example, acid such as nitric acid and the like, acetylacetone, polyethyleneglycol, triton X-100, and the like.

Hereinafter, referring to FIGS. 3A and 3B, explained is why a crack is generated on a coating film 12.

When a coating film 12 for coating a current-collecting electrode 11 is disposed by sintering a glass paste composition with a low-melting point, impurities or a binder may remain in the glass paste composition. When the impurities or the binder resin is combusted with the glass paste composition, gas is produced, making a hole in coating film 12

As shown in FIG. 3A, this hole may have various sizes ranging from a big one B_{L} made by gas having big volume and another big hole B_{C} agglomerated by more than one small hole to a small hole B_{S} and various shapes.

The research on relationship between coating film 12 and its electrolyte resistance shows that the hole size in coating film 12 has an influence on the electrolyte resistance during the sintering of the glass paste composition.

In other words, as shown in FIG. 3A, when coating film 12 had big holes B_{L} and B_{C}, coating film 12 may easily have a crack, which may result in corrosion of the underlying current-collecting electrode 11.

On the other hand, as shown in FIG. 3B, when coating film 12 has a small-sized hole (B_{S}), the hole may simultaneously suppress a crack in coating film 12 and, corrosion of the underlying current-collecting electrode 11 by electrolyte solution 5 flown therethrough, thus securing the electrolyte resistance.

However, a hole size for securing electrolyte resistance is hard to determine depending on thickness of coating film 12. But the hole may have a maximum length of less than a half of the thickness of coating film 12, in order to secure electrolyte resistance.

According to the embodiment of the present invention, the maximum length indicates the longest length among different cross sections of the holes, when coating film 12 is cut parallel to or vertically against transparent electrode 10. For example, the maximum length may be a diameter in a circular hole or a longer one in an oval hole.

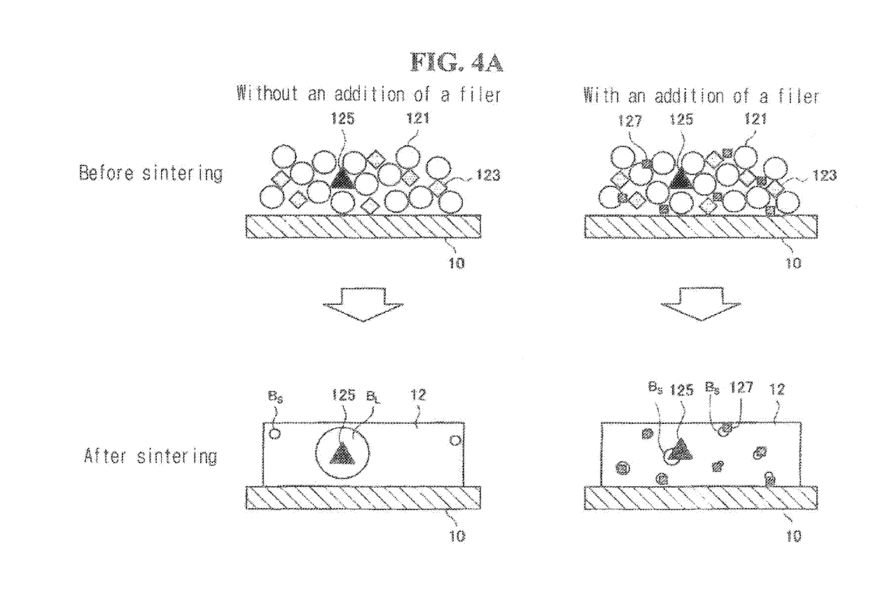

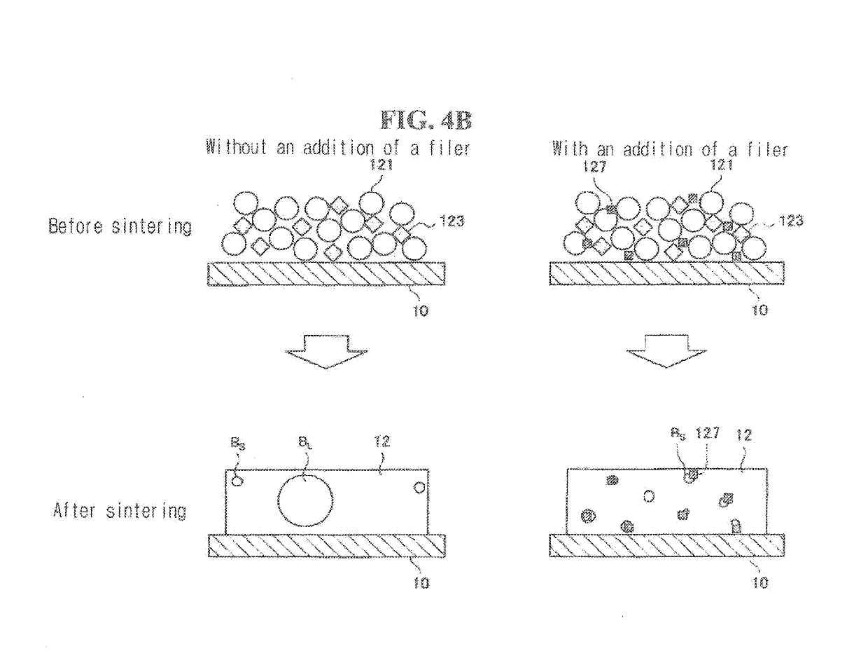

Next, referring to FIGS. 4A and 4B, explained is why a big hole is generated in a coating film 12.

FIG. 4A illustrates hole generation condition, when debris or dirt is included in a glass paste composition, and FIG. 4B illustrates hole generation condition, when a glass paste composition is over-sintered.

As described above, a glass paste composition for coating film 12 according to the embodiment of the present invention may include glass frit 121, a binder resin 123 for binging glass frit 121, a solvent (not shown), and an additive (not shown), but also, dirt 125 as an impurity as shown in the left top figure of FIG. 4A.

When a glass paste composition including dirt 125 is sintered, binder resin 123 remaining during the sintering becomes gaseous and generates vapors, which are gathered around impurities such as dirt 125 and the like.

As a result, the vapors close each other are gathered together and become bigger and thus, form a big hole (B_{L}) around dirt 125 as shown in the left bottom figure of FIG. 4A.

Herein, impurities such as dirt 125 and the like are in general hard to completely remove. Their complete removal could deteriorate production efficiency, considering additional process and cost.

In addition, the glass paste composition is treated with a predetermined treatment. As shown in the left top figure of FIG. 4B, its process margin needs to be secured to prevent lack of sintering due to deviation of glass paste composition materials and the like, even though impurities are completely removed.

Accordingly, the glass paste composition may be sufficiently sintered not under lowest sintering conditions (sintering temperature, time, or the like) but under a little over-sintering conditions (higher sintering temperature or a little longer sintering time).

In this way, when a glass paste composition is over sintered, small vapors are gathered to form a bigger hole (B_{L}) as shown in the left bottom figure of FIG. 4B.

Accordingly, in order to suppress generation of a big hole (B_{L}) due to dirt 125 or over-sintering, as shown in the right top figures of FIGS. 4A and 4B, a filler 127 with a predetermined particulate type may be included in the glass paste composition. The resulting glass paste composition is dispersed and sintered. As shown in the right bottom figures of FIG. 4A or 4B, small vapors are not gathered but form a small hole (B_{S}) around filler 127.

The reason is as follows.

First of all, as shown in the right top figure of FIG. 4A, when a glass paste composition includes impurities such as dirt 125 and the like, a filler 127 is dispersed therein. Thus, a plurality of particles including impurities such as dirt 125 and the like and filler 127 may be overall dispersed into the glass paste composition.

When this glass paste composition is sintered, vapors generated during the sintering are not gathered around a few impurities but dispersed around a few impurities and lots of fillers 127 and thus, do not become big. Thus, a big hole (B_{L}) may not be formed but suppressed as shown in the right bottom figure of FIG. 4A.

In addition, as shown in the right top figure of FIG. 4B, a glass paste composition includes no impurity such as dirt 125 and the like.

In other words, when a glass paste composition including a plurality of fillers 127 dispersed therein is sintered, vapors generated during the sintering are dispersed around the plurality of fillers 127 rather than become bigger, suppressing formation of a big hole (B_{L}) as shown in the right top figure of FIG. 4B.

In this way, since a filler 127 is dispersed in a glass paste composition and suppresses formation of a big hole (B_{L}) in a coating film 12, coating film 12 may have improved strength.

Accordingly, a glass paste composition according to the embodiment of the present invention may prevent formation of a crack in coating film 12, resultantly accomplishing electrolyte resistance. In addition, when filler 127 is added to the glass paste composition, the glass paste composition may improve strength of coating film 12 and may prevent a crack formed by the contact between coating film 12 and current-collecting electrode 11 on counter electrode 4 when a photoelectric transformation cell is fabricated.

Hereinafter, a filler for the glass paste composition is described in more detail.

The filler may be made of a material that is not melted at the aforementioned melting temperature of transparent electrode 10 or less, that is, a temperature where transparent electrode 10 may not physically and chemically maintain a shape. In particular, the melting temperature here refers to a glass transition temperature or a phase transition temperature of transparent electrode 10.

Here in the specification and the claims, ‘a filler is not melted’ means that a filler maintains a physical and chemical shape at a glass transition temperature or a phase transition temperature of transparent electrode 10 or less. For example, when a transparent electrode 10 is made of a transparent conductive oxide (TCO), a filler may not be melted but maintain a physical and chemical shape at the glass transition temperature of 600° C. or less of transparent electrode 10 made of TCO.

Accordingly, when a filler includes, for example, a metal oxide, it has a higher phase transition temperature than a glass transition temperature or a phase transition temperature of transparent electrode 10. When a filler includes, for example, a glass material, it also has a higher glass transition temperature than a glass transition temperature or a phase transition temperature of transparent electrode 10.

Examples of the filler material, that is, a material that is not melted at a glass transition temperature or a phase transition temperature of transparent electrode 10 or less, and may include at least one oxide selected from Al₂O₃, SiO₂, TiO₂, ZnO₂, SnO₂, MgO, and CaO.

When the oxide as a filler is included in a glass paste composition, the oxdie may surely suppress formation of a big hole in a coating film 12. Accordingly, Al₂O₃ and SiO₂ as a filler material are preferable.

The filler may be included in an amount of about 0.1 to 50 wt % based on a glass paste composition. When the filler is included within the range, the filler may effectively suppress formation of a big hole in a coating film 12 (suppress gathering of vapors when a glass paste composition is sintered).

On the other hand, when the filler is included in an amount of less than about 0.1 wt %, the filler may not effectively suppress the formation of the big hole. When included in an amount of more than about 50 wt %, the filler particles stand side by side and form a passage for an electrolyte solution on the interface with a glass component, through which the electrolyte solution may reach a current-collecting electrode. In addition, a plurality of filler particles may be agglomerated into a big chuck, around which a crack may be generated on a coating film 12.

Furthermore, a filler may be added in an amount of about 0.1 to 20 wt % and preferably, in an amount of about 0.1 to 10 wt % to suppress the formation of the big hole on coating film 12.

When the filler has an extremely small particle diameter, the filler may not be easily dispersed into the glass paste composition. The dispersion of the filler needs to be improved by adding a dispersion additive and the like to a glass paste composition or increasing its dispersion time.

On the other hand, when a filler has an extremely big particle diameter against the thickness of coating film 12, coating film 12 may be relatively thin and thus, have deteriorated strength and a crack around the filler.

Accordingly, a filler may have a particle, diameter ranging from about 0.1 μm to 10 μm.

On the other hand, the dispersion additive for improving dispersion of a filler may be formed of at least one selected from glycerine fatty acid estermonoglyceride, polyglycerine fatty acid ester, special fatty acid ester, propyleneglycol fatty acid ester, and the like.

In addition, the filler has a so-called 50% particle diameter D50 (called to be ‘a median diameter’). The particle diameter D50 of a filler indicates a diameter exactly dividing particles and particulates by 50% depending on the number distribution of particle sizes.

Hereinafter, illustrated is a method of manufacturing the aforementioned photoelectric transformation device 1 in detail.

### Fabrication of a Positive Electrode

First of all, a transparent electrode 10 is fabricated by disposing a transparent conductive oxide (TCO) such as indium tine oxide (ITO), tin oxide (SnO₂), or fluorine-doped tin oxide (FTO), antimony-containing tin oxide (ITO/ATO), zinc oxide (ZnO₂) and the like, on the surface of a substrate 2 such as a glass substrate, a transparent resin substrate, or the like in a sputtering method.

Next, a paste composition including a metal with high conductivity such as Ag, Ag/Pd, Cu, Au, Ni, Ti, Co, Cr, Al, and the like or its alloy, a resin, a solvent, and the like is disposed and coated on transparent electrode 10 to have a structure securing best photoelectric transformation efficiency (e.g., a comb teeth type).

The paste composition may be disposed in a method of, screen-printing, coating with a dispenser, Inkjet-printing, a metal mask method, and the like.

In addition, the coated paste composition is dried at a temperature ranging from about 80 to 200° C. for removing the solvent and then, sintered at a temperature ranging from about 400 to 600° C. for removing the resin and sintering the metal, fabricating a current-collecting electrode 11.

Then, current-collecting electrode 11 is covered with a glass paste composition on the surface to form a coating film 12.

In particular, the glass paste composition is prepared by dispersing the aforementioned glass frit, a binder resin binding the glass frit, and an additive added for a need into water or an appropriate solvent.

Herein, the aforementioned filler is added for dispersing the glass paste composition as described later.

Next, the prepared glass paste composition is coated to cover all over the current-collecting electrode 11 except for a region connected to a lead wire 7 (a drawing-out region).

The glass paste composition may be coated, for example, in a screen-printing method, a coating method using a dispenser, an Inkjet-printing method, and the like.

Since coating film 12 is made of a material with low conductivity, however, coating film 12 is sufficiently required to cover current-collecting electrode 11 but be small thereon in teems of improving photoelectric transformation efficiency.

In addition, coating film 12 is dried at a temperature ranging from about 80° C. to 200° C. where the solvent in the coated glass paste composition is removed and then, sintered at a temperature ranging from about 400 to 600° C. where the binder resin in the coated glass paste composition is removed and the glass flit therein is sintered.

Hereinafter, a method of preparing a glass paste composition according to one embodiment of the present invention and in particular, a method of adding a filler is illustrated in detail.

A glass paste composition is prepared by mixing, for example, vehicle components such as a binder resin, a solvent, an additive, and the like and adding powder components such as glass frit and the like thereto and then, dispersing the powder components into the vehicle components using a roll mill and the like.

Herein, a filler is added to the powder component. The mixture is mixed with glass frit. The powder component including the glass frit and the filler is dispersed into a vehicle component, preparing a glass paste composition according to one embodiment of the present invention.

The filler does not, however, need to be added to the powder component, before glass frit is added thereto. Alternatively, after glass frit is mixed with (or dispersed into) a vehicle component, a filler may be added to the mixture. Herein, after the filler is added thereto, the filler may be dispersed using a roll mill.

In this way, there is no particular limit in the time when a filler is added and also, no limit in a method of preparing a glass paste composition using a roll mill or a mechanical dispersion method similar to this after mixing all the components, as long as the method can disperse glass frit and the filler.

On the other hand, the roll mill is a dispenser having three rolls (mainly made of ceramic) respectively having different rotation speeds and directions. According to the roll mill, a powder component (solid) such as glass frit, a filler, or the like can be dispersed into a vehicle by passing the vehicle through three rolls with rotation speeds and directions.

Then, a counter electrode 4 is fabricated by disposing a metal (platinum, gold, silver, copper, aluminum, rhodium, indium, and the like), a metal oxide (indium tin oxide (ITO), tin oxide (including tin oxide doped with fluorine and the like), zinc oxide, and the like), a conductive carbon material, a conductive organic material, or the like in an active area (area available for photoelectric transformation) on the surface of an electrode substrate including transparent electrode 10, current-collecting electrode 11, and coating film 12 in a sputtering method and the like.

### Fabrication of a Negative Electrode

First of all, prepared is an electrode substrate including a transparent electrode 10, a current-collecting electrode 11, and a coating film 12 on the surface of a substrate 2.

Next, a paste composition is prepared by dispersing metal oxide particulates 31 such as TiO₂ and the like (preferably, a particulate with a particle diameter of an order of nanometer) and a binder resin for binding them into water or an appropriate organic solvent.

Then, the paste composition is coated in an active area (area available for photoelectric transformation) on the surface of the electrode substrate.

The paste composition may be coated, for example, using screen-printing, a dispenser, a spin-coating, Squeegee, a dip-coating, spraying, dye-coating, Inkjet-printing, and the like.

Next, the paste composition is dried at a temperature ranging from about 80 to 200° C. where a solvent therein is removed and then, sintered at a temperature ranging from about 400 to 600° C. where a binder resin therein is removed and the metal oxide particulates are sintered, forming a metal oxide semiconductor layer.

In addition, the prepared metal oxide semiconductor layer as well as the electrode substrate is dipped in a solution in which a sensitizing dye unit 33 is dissolved (e.g., an ethanol solution of ruthenium complex-based pigment) for a couple of hours to bind sensitizing dye unit 33 to the surface of the metal oxide particulate 31 by using the affinity of connecting group 35 of sensitizing dye unit 33.

Finally, the metal oxide semiconductor layer combined with sensitizing dye unit 33 is dried at a temperature ranging from about 40 to 100° C. where a solvent therein is removed, forming a photoelectrode 3.

On the other hand, the method of combining sensitizing dye unit 33 with the surface of metal oxide particulates 31 is not limited thereto.

### Connection of Positive and Negative Electrodes

The obtained positive electrode is placed to face the negative electrode, and then, a spacer (for example, an ionomer resin such as Himilan (trade name) manufactured by Mitsui DuPont Polychemical, and the like) is disposed in a connection part around each substrate 2. Then, the positive and negative electrodes are thermally bound at a temperature of about 120° C.

The electrolyte solution (for example, an acetonitrile electrolyte solution dissolved with Lil and I₂) is injected into a space defined by the positive electrode, the negative electrode and the spacer through an injection hole and widely spread in the entire cell, providing a photoelectric transformation device 1.

A plurality of photoelectric transformation devices 1 may be connected and associated, if required. For example, a plurality of photoelectric transformation devices 1 is associated in series to increase the overall generating voltage.

Hereinbefore, one embodiment of the present invention is illustrated in detail referring to accompanied drawings but not limited thereto.

Each exemplary variation or modification within the spirit and scope of the appended claims is clearly understood to belong to technological range of the present invention by those who have common knowledge in the related art.

For example, a metal oxide particulate 31 is illustrated as an inorganic semiconductor particulate having a photoelectric transformation function and connected with a sensitizing dye on the surface. But, the present invention is not limited thereto and may include an inorganic semiconductor particulate rather than a metal oxide.

The inorganic semiconductor particulate rather than a metal oxide may include a compound such as silicon, germanium, Group III-V-based semiconductor, metal chalcogenide, and the like.

The following examples illustrate this disclosure in more detail. These examples, however, are not in any sense to be interpreted as limiting the scope of this disclosure.

In the present exemplary embodiment, an electrolyte solution for a coating film is evaluated regarding durability (electrolyte resistance), influence on the particle diameter of a filler due to a hole, mechanical strength, and photoelectric transformation efficiency as a dye-sensitized solar cell.

### Durability Evaluation of an Electrolyte Solution

First of all, an electrolyte solution for a coating film was evaluated regarding durability.

### Formation of a Current-collecting Electrode

A current-collecting electrode was fabricated by screen-printing an Ag paste (MH1085, Tanaka Holdings Co., Ltd.) on a glass substrate (Type U-TCO, 112 mm×106 mm×1 mm thickness, Asahi Techno Glass Corp.) having a fluorine-doped tin oxide (FTO) layer, which is a transparent electrode layer to have sixteen (16) stripe lines with 0.5 mm width×100 mm length and 10 μmm thickness.

### Preparation of a Glass Paste Composition

A glass paste composition was prepared by mixing 5 g of an ethyl cellulose resin (removal temperature: about 400° C.), 60 g of glass frit (B₂O₃—SiO₂—Bi₂O₃-based, glass softening point (Ts): 475° C.), 30 g of terpineol (Kanto Chemical Co.), 5 g of butylcarbitol acetate (Kanto Chemical Co.), and a particular kind of filler in a particular amount provided in Table 1 and sufficiently dispersing them with a three roll mixer.

On the other hand, the amount of filler is provided in Table 1 based on 100 parts by weight of the entire amount of an ethyl cellulose resin, glass frit, terpineol, and butylcarbitol acetate.

### Formation of Coating Film

The prepared glass paste composition is used to completely cover a current-collecting electrode and to form a 1 mm-wide striped pattern in a screen printing method.

Next, the resulting product was dried in a 150° C. oven to remove a solvent in the glass paste composition and sintered at 500° C. for 30 minutes under air atmosphere to remove a binder resin component therein, forming a coating film. Herein, the sintering temperature indicates a highest temperature that a glass paste composition can reach.

### Fabrication of a Cell for Evaluation

Each glass substrate and FTO glass substrate on which the current-collecting electrode was respectively disposed was hot-pressed using a hot-melt resin ‘Himilan (thickness: 120 μm)’. Then, an electrolyte solution was injected into a predesigned hole. The hole was sealed using Himilan or a glass cover, fabricating a cell for evaluation.

### Evaluation of Electrolyte Resistance

The cell for evaluation was allowed to stand at 85° C. for 864 hours and examined regarding condition and shape of the current-collecting electrode and the coating film.

The cells according to Examples 1 to 16 and Comparative Example 1 were examined with a microscope. Table 1 shows the number of errors through the examination. Herein, ‘the number of errors’ indicates how many damages were done on a current-collecting electrode by cracks of a coating film.

TABLE 1

| | | Amount of filler | Number |
|---|---|---|---|
| | Filler | [parts by weight] | of error |
| Example 1 | Al₂O₃ | 0.1 | 0 |
| Example 2 | Al₂O₃ | 1 | 0 |
| Example 3 | Al₂O₃ | 5 | 1 |
| Example 4 | Al₂O₃ | 10 | 3 |
| Example 5 | Al₂O₃ | 20 | 5 |
| Example 6 | SiO₂ | 0.1 | 0 |
| Example 7 | SiO₂ | 1 | 0 |
| Example 8 | SiO₂ | 5 | 0 |
| Example 9 | SiO₂ | 10 | 1 |
| Example 10 | SiO₂ | 20 | 4 |
| Example 11 | TiO₂ | 1 | 1 |
| Example 12 | TiO₂ | 5 | 4 |
| Example 13 | TiO₂ | 10 | 4 |
| Example 14 | ZnO | 1 | 1 |
| Example 15 | ZnO | 5 | 1 |
| Example 16 | ZnO | 10 | 3 |
| Comparative | None | — | 23 |
| Example 1 | | | |

Referring to Table 1, the cells including a filler according to Examples 1 to 16 were found to have remarkably less errors than the one including no filler according to Comparative Example 1.

Accordingly, when a coating film is disposed using a glass paste composition, the filler disperses vapors, which suppresses a big hole from being formed in the coating film and thus, a crack thereon.

In addition, Al₂O₃ and SiO₂ among the four fillers evaluated above turned out to have the best effects on suppressing a crack on a coating film.

Furthermore, when the filler was included in an amount ranging from about 0.1 wt % to 20 wt %, the filler had good effect. In particular, when added in an amount ranging from about 0.1 wt % to 10 wt %, the filler had better effect.

### Particle Diameter of A Filler Having an Influence on Hole Generation

Research was made on dispersion of a filler and generation of a hole in a coating film, when the filler had various particle diameters.

In particular, a plurality of filler samples with various particle diameters was used in the same amount to prepare each glass paste composition. The glass paste compositions were respectively disposed on a current-collecting electrode to form a coating film. The coating films were examined on the surface of the current-collecting electrode with a metal microscope or a laser microscope.

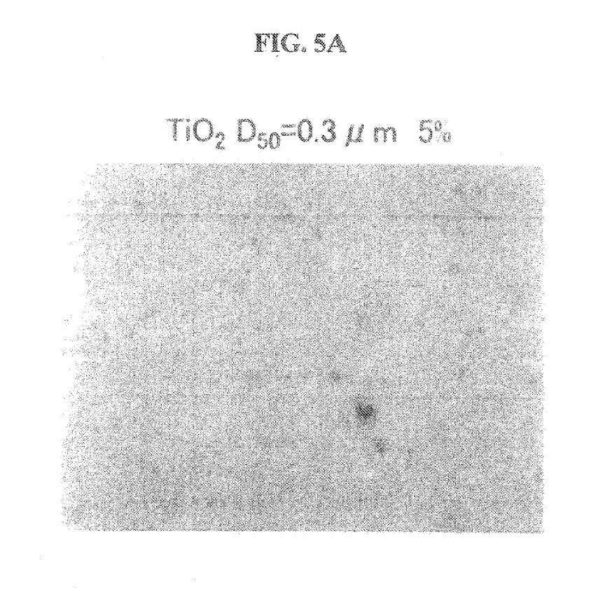

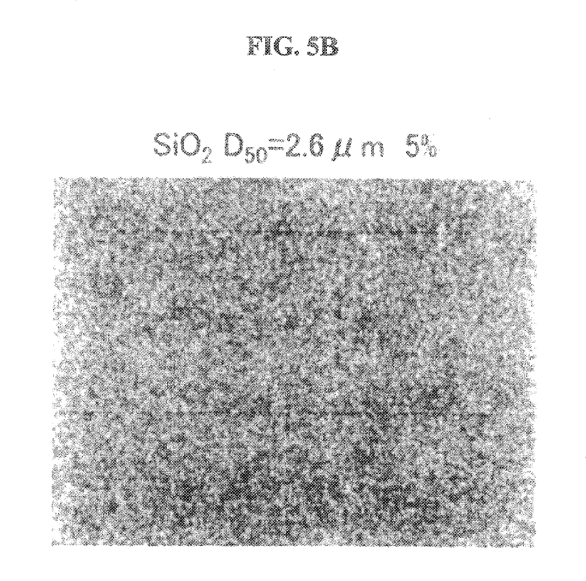

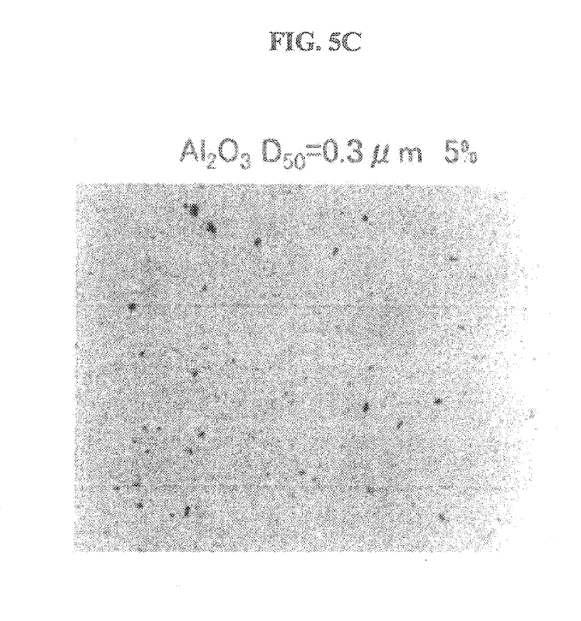

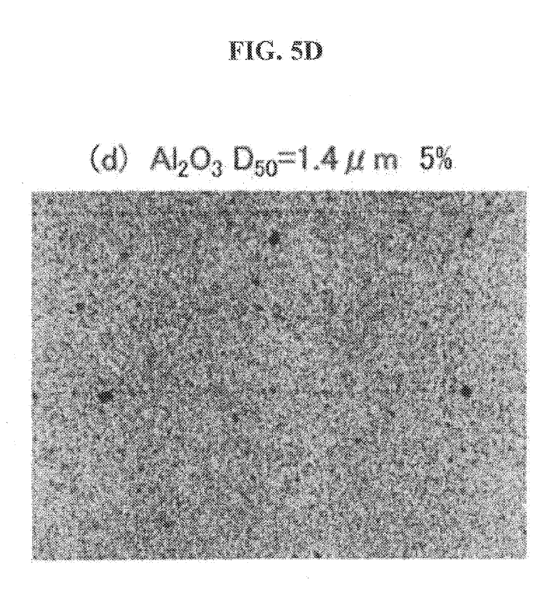

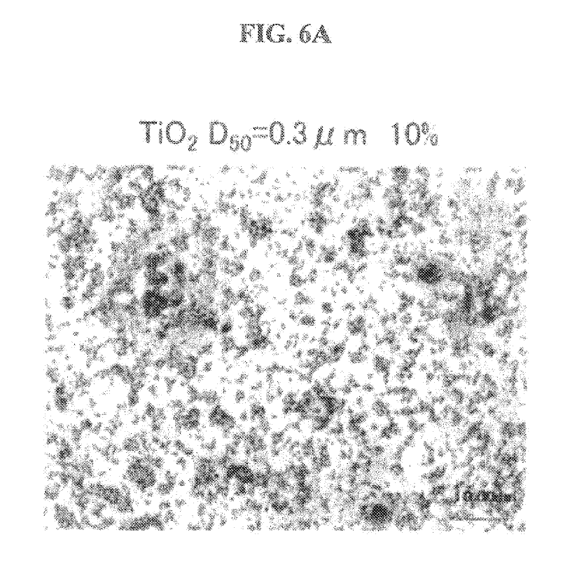

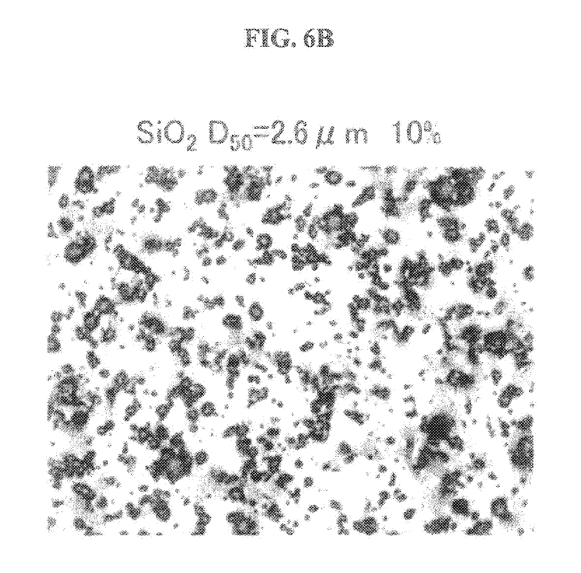

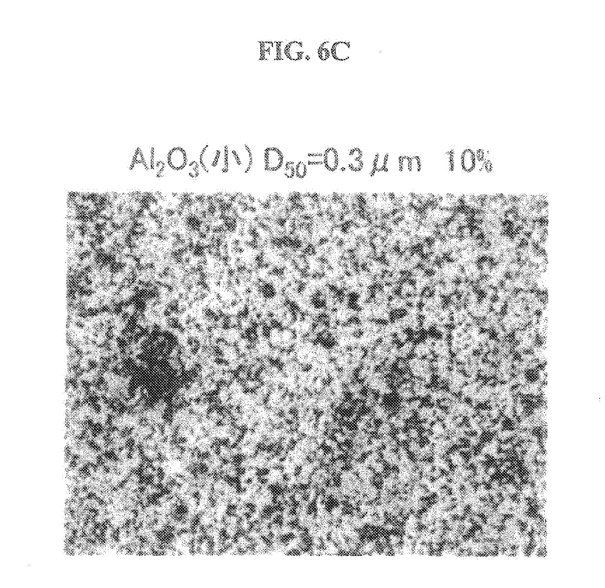

The results are provided in FIGS. 5 and 6 which have the same dimension.

FIG. 5 is a photograph showing the surface of a coating film examined with a metal microscope, while FIG. 6 is a photograph showing the surface of the coating film examined with a laser microscope.

In FIGS. 5 and 6, provided are the kinds of filler, 50% particle diameter (D₅₀), and the amount (%=a weight base) in order.

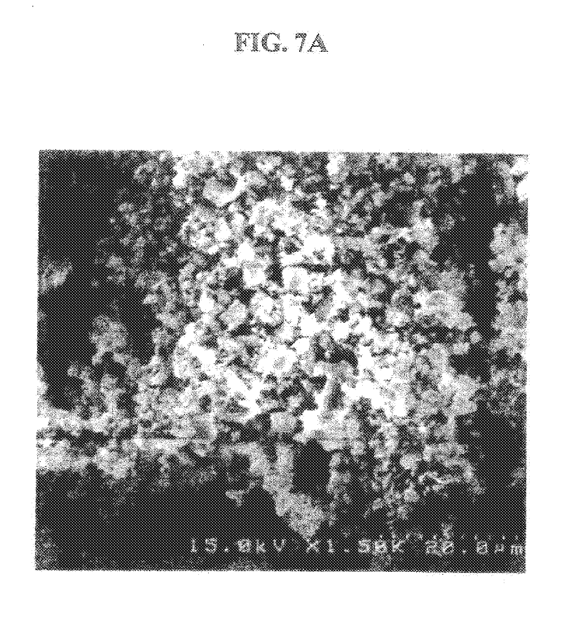

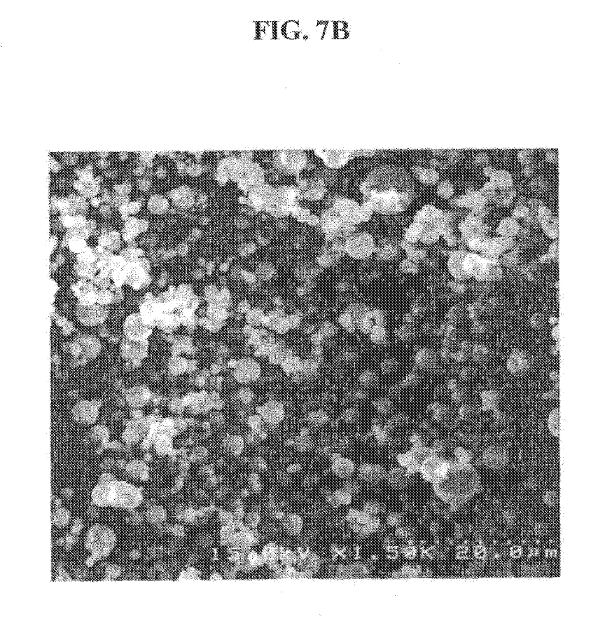

FIG. 7 provides a photograph of a filler itself examined on the surface of the substrate with an electron microscope.

Referring to FIGS. 5 and 6, a big hole was in general not found regardless of the kind, particle diameter, and the amount of the filler. Accordingly, this result indicates that the filler suppresses formation of big holes in a coating film.

However, comparing FIGS. 5A, 5C, 6A, and 6C with FIGS. 5B, 5D, and 6B, the coating films including a filler with a relatively small particle diameter had more big holes or less filler dispersion.

### Mechanical Strength of Coating Film

The coating film was evaluated regarding mechanical strength according to strength test.

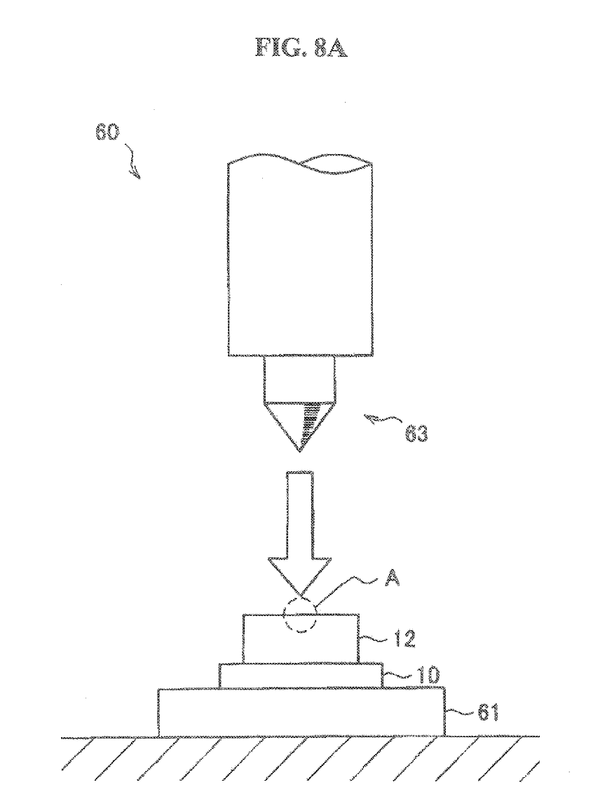

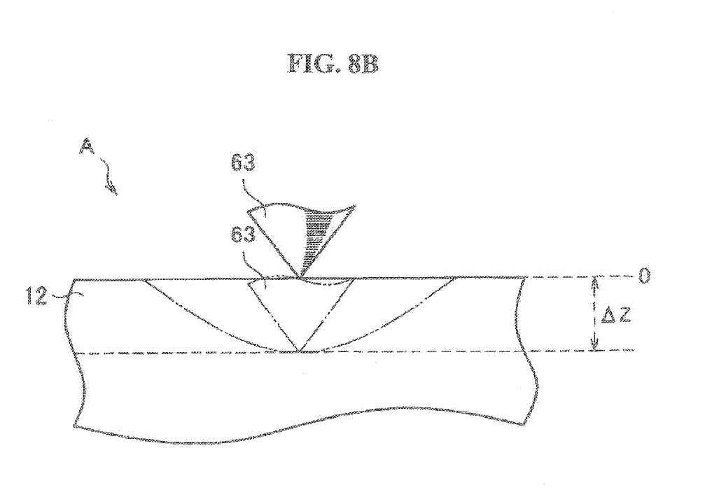

First of all, illustrated is strength test referring to FIG. 8.

FIG. 8A is a synopsis showing a test method using a strength tester. FIG. 8B is a view enlarging a region A marked with a dotted line in FIG. 8A.

Referring to FIG. 8A, a strength tester 60 is a device for measuring displacement (a press distance) of a depressor 63 and its compressive power applied to a sample by contacting depressor 63 with the sample coating film 12 formed on a transparent electrode 10 on a measurement subtrate 61 and pressing depressor 63 on the surface of the sample again.

Depressor 63 has a cone-shape with a diameter of 50 μm, a maximum stroke (movable distance) of about 100 μm, and a maximum compressive strength of about 4000 mN.

When strength tester 60 was used to measure strength of coating film 12 loaded on measurement substrate 61, the sample coating film 12 was first loaded on measurement substrate 61, and then, depressor 63 was moved on coating film 12. Herein, depressor 63 is moved to a predetermined place by using, for example, object lens (not shown) and the like equipped around depressor 63.

Next, depressor 63 was perpendicularly plumbed toward the surface of the sample coating film 12 and contacted therewith, as shown in FIG. 8B. Herein, the position of depressor was set at 0.

Then, when depressor 63 was perpendicularly plumbed toward the surface of the sample coating film 12 again, the surface of coating film 12 was pushed by depressor 63.

Strength tester 60 was used to measure the displacement (falling distance from 0 position of the depressor) ΔZ μm of depressor 63 and its compressive power (mN) applied to coating film 12 herein, when the surface of the coating film 12 was compressed by depressor 63.

In this way, a glass substrate (Reference Example), a coating film including no filler (Comparative Example), a coating film including 10 wt % of SiO₂ as a filler (Example), a coating film including 10 wt % of Al₂O₃ as a filler (Example), and a coating film including 10 wt % of TiO₂ as a filler (Example) were measured regarding relationship between displacement ΔZ μm of depressor 63 and its compressive power (mN) applied thereto at that time.

### Strength Test Result

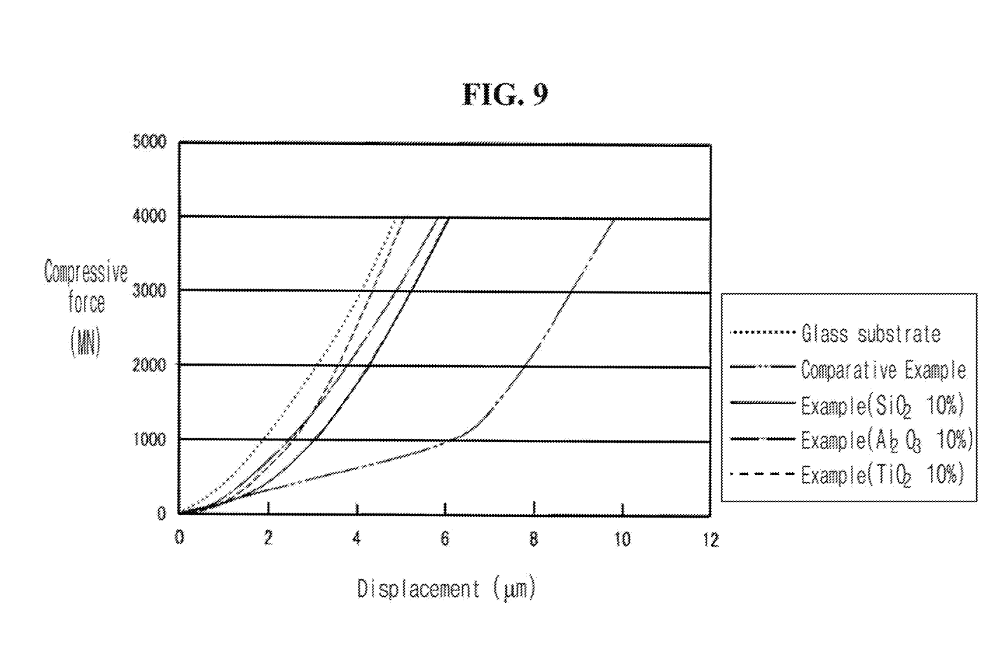

The strength test results are provided in FIG. 9.

FIG. 9 provides a graph showing strength test results according to the embodiment of the present invention.

Referring to FIG. 9, the coating films respectively including SiO₂, Al₂O₃ and TiO₂ as a filler in an amount of 10 wt % had almost similar strength to a glass substrate.

On the other hand, a coating film including no filler according to Comparative Example had sharply deteriorated strength compared with a glass substrate or the coating films according to each Example.

Based on the above result, since a filler is included in a coating film according to each Example and disperse holes around, the filler may suppress formation of a big hole and thus improve strength of the coating layer itself. Accordingly, the filler may suppress a crack on the coating layer contacting with a counter electrode and thus, decrease the number of errors.

On the other hand, since the coating filler included no filler according to Comparative Example, holes were mainly formed around impurities such as dirt and the like, becoming big. These big holes brought about a crack on the coating film and thus, lots of errors such as corrosion of a current-collecting electrode may be undesirably generated.

### Performance Evaluation of Dye Sensitized Solar Cell

The coating films according to Examples 3 and 8 and Comparative Example 1 were respectively used to form an electrode substrate. The electrode substrate was used to fabricate a dye sensitized solar cell. Then, the dye sensitized solar cell was evaluated regarding photoelectric transformation efficiency η.

### Counter Electrode

A counter electrode was fabricated by laminating a 150 nm thick platinum electrode layer on an electrode substrate respectively having the coating layers according to Examples 3 and 8 and Comparative Example 1 in a sputtering method.

Preparation of a Paste Composition for a Photoelectrode (a Titanium Oxide electrode)

Prepared was a paste composition for a photoelectrode.

In particular, 3 g of titanium oxide particulate (P-25, Nippon Aerosil), 0.2 g of acetyl acetone, and 0.3 g of a surfactant (polyoxyethylene octylphenylether) were bead-milled with 7.0 g of terpineol. The treated product was dispersed for 12 hours.

In addition, 1.0 g of an ethylcellulose resin was added thereto as a binder resin, preparing a paste composition.

The paste composition had enough viscosity to perform, for example, a screen-printing at a shear rate of 10 sec⁻¹.

### Fabrication of a Titanium Oxide Electrode

Prepared was a titanium oxide electrode including a titanium oxide particulate.

In particular, a titanium oxide electrode including a titanium oxide porous layer with a thickness of 10 μm and an active area of 100 cm² was fabricated by applying the paste composition prepared as aforementioned on the conductive surface of each electrode substrate having a coating film according to Examples 3 and 8 and Comparative Example 1 in a screen printing method and sintering the applied paste composition for one hour in a 450° C. oven.

### Absorption of a Sensitizing Dye

A sensitizing dye is absorbed in a titanium oxide electrode prepared as aforementioned in the following method.

A sensitizing dye of photoelectric transformation N719 (Solaronix Co., Ltd.) was dissolved in ethanol having a concentration of 0.6 mmol/L to prepare a dye solution. The titanium oxide electrode was dipped in the dye solution and allowed to stand at a room temperature for 24 hours.

The colored titanium oxide electrode was cleaned on the surface and then, dipped in a 2 mol % alcohol solution of 4-t-butylpyridine for 30 minutes and dried at a room temperature, preparing the photoelectrode with a titanium oxide porous layer absorbing a sensitizing dye.

### Preparation of an Electrolyte Solution

An electrolyte solution was prepared by adding 0.1M LiI and 0.05 M I2 as an electrolyte, and 0.5M 4-t-butylpyridine and 0.6 M 1-propyl-2,3-diemthylimidazolium iodide to a solvent.

The solvent for dissolving an electrolyte may include methoxy acetonitrile.

### Assembly of a Photoelectric Transformation Cell

A test sample photoelectric transformation cell (a photoelectric transformation device) shown in FIG. 1 was assembled using a photoelectrode and a counter electrode fabricated as aforementioned.

In other words, the photoelectrode and the counter electrode were fixed with a spacer made of a resin film (a 120 μm-thick tilimilani film, DuPont-Mitsui Polychemical) therebetween. Then, the electrolyte solution was injected therein, forming an electrolyte solution layer.

Then, a wire for measuring transformation efficiency is respectively connected to a glass substrate.

### Measurement of Transformation Efficiency

The photoelectric transformation cells according to Example and Comparative Example were measured regarding transformation efficiency in the following method.

A solar simulator made by Oriel Inc. was assembled with an air mass filter. Then, a test sample photoelectric transformation cell was measured regarding I-V curve characteristic using a Keithley Model 2400 source meter while a light was radiated therein using a light source adjusted to be 100 mW/cm² of a light amount.

The transformation efficiency (%) of the photoelectric transformation cell was calculated according to the following transformation efficiency equation 1 using Voc (open-circuit voltage value), Isc (short-circuit current value), ff (fill factor value) acquired from the I-V curve characteristic measurements.

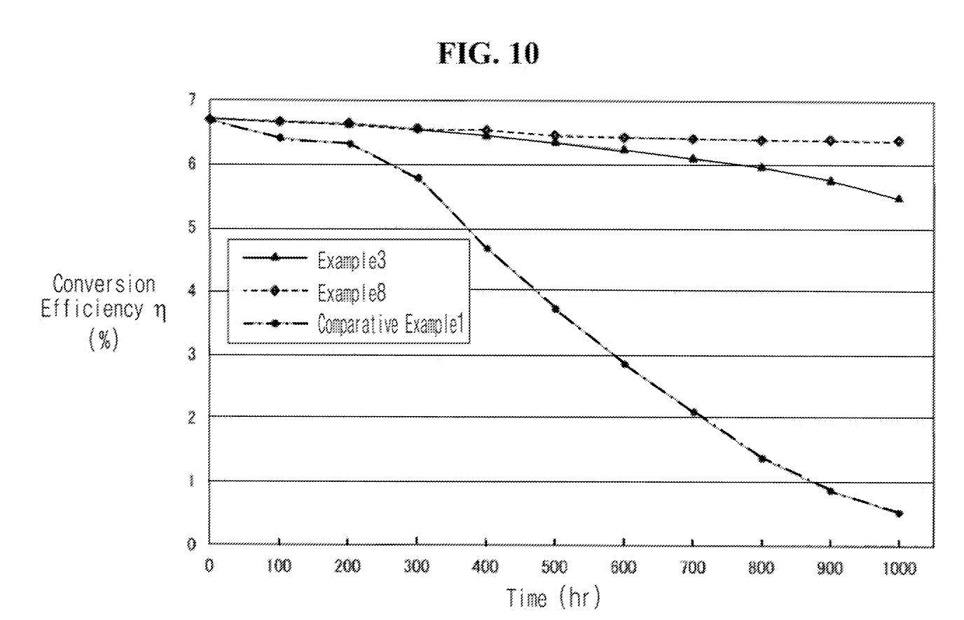

FIG. 10 is a graph showing the transformation efficiency values versus time of the photoelectric transformation cells according to Example and Comparative Example.

FIG. 10 is a graph showing relationship between transformation efficiency η of the photoelectric transformation cells constructed according to Examples 3 and 8 and Comparative Example 1 and time.

$$\begin{matrix}( Equation 1 ) & \\ η ( \% ) = \frac{Voc ( V ) \times Isc ( mA ) \times ff}{100 ( \overline{m} W / {cm}^{2} ) \times 100 {cm}^{2}} \times 100 & ( 1 )\end{matrix}$$

Referring to FIG. 10, the photoelectric transformation cells according to Examples 3 and 8 and Comparative Example 1 all had higher transformation efficiency of about 6% or more than the initial photoelectric transformation.

However, the photoelectric transformation cell of Comparative Example 1 had sharply deteriorated transformation efficiency as time goes. On the contrary, the photoelectric transformation cells of Examples 3 and 8 maintained high transformation efficiency regardless of time.

The reason is that the photoelectric transformation cell of Comparative Example 1 had lots of big holes and thus, a crack in the coating film therein. Accordingly, a current-collecting electrode is corroded by an electrolyte solution, deteriorating transformation efficiency.

On the other hand, the photoelectric transformation cells of Examples 3 and 8 were suppressed from formation of a big hole in a coating film and thus, a crack therein. Accordingly, a current-collecting electrode was not almost corroded, maintaining transformation efficiency of the cell.

In this way, when a glass paste composition including a filler is applied to form a coating film, the coating film was suppressed from having a big-sized hole.

As a result, the coating film had no crack (split), which prevented the current-collecting electrode from contacting with an electrolyte solution and thus, corrosion of the current-collecting electrode.

Therefore, a photoelectric transformation device such as a dye sensitized solar cell and the like including this electrode substrate may have high efficiency, long life-span, and high durability.

As disclosed above, an electrode substrate according to the principles of the present invention is constructued with a transparent conductive substrate, a current-collecting electrode disposed on the transparent conductive substrate, and a coating film coating a surface of the current-collecting electrode. The coating film includes a combustion product of a glass paste composition applied on the surface of the current-collecting electrode. The glass paste composition includes a filler made of a material that does not melt at a temperature which is not higher than a glass transition temperature or a phase transition temperature of the transparent conductive substrate.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. An electrode substrate, comprising
a transparent conductive substrate comprising a transparent electrode and a substrate;
a current-collecting electrode disposed on the transparent conductive substrate; and
a coating film coating a surface of the current-collecting electrode,
the coating film comprises a combustion product of a glass paste composition applied on the surface of the current-collecting electrode, and
the glass paste composition comprises a filler made of a material that does not melt at a temperature which is not higher than a glass transition temperature or a phase transition temperature of the substrate.

2. The electrode substrate of claim 1, wherein the filler is comprised in the glass paste composition in an amount of about 0.1 wt % to about 50 wt % based on the total weight of the glass paste composition.

3. The electrode substrate of claim 1, wherein the filler comprises at least one of Al₂O₃, SiO₂, TiO₂, ZnO₂, SnO₂, MgO, and CaO.

4. The electrode substrate of claim 1, wherein the filler has a particle diameter of about 0.1 μm to about 10 μm.

5. A photoelectric transformation device, comprising:
an electrode substrate comprising
a transparent conductive substrate;
a current-collecting electrode disposed on the transparent conductive substrate; and
a coating film coating a surface of the current-collecting electrode,
the coating film comprises a combustion product of a glass paste composition applied on the surface of the current-collecting electrode, and
the glass paste composition comprises a filler made of a material that does not melt at a temperature which is not higher than a glass transition temperature or a phase transition temperature of the transparent conductive substrate.

6. The photoelectric transformation device of claim 5, wherein the photoelectric transformation device is a dye sensitized solar cell.

7. The photoelectric transformation device of claim 5, wherein the filler is comprised in the glass paste composition in an amount of about 0.1 wt % to about 50 wt % based on the total weight of the glass paste composition.

8. The photoelectfic transformation device of claim 5, wherein the filler comprises at least one of Al₂O₃, SiO₂, TiO₂, ZnO₂, SnO₂, MgO, and CaO.

9. The photoelectric transformation device of claim 5, wherein the filler has a particle diameter of about 0.1 μm to about 10 μm.
